(19) United States
(12) Patent Application Publication
(10) Pub. No.: US 2009/0047766 A1
(43) Pub. Date: Feb. 19, 2009

(54) METHOD FOR FABRICATING RECESS CHANNEL MOS TRANSISTOR DEVICE

(76) Inventor: Shian-Jyh Lin, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/970,465

(22) Filed: Jan. 7, 2008

(30) Foreign Application Priority Data
Aug. 14, 2007 (TW) 096130006

(51) Int. Cl. H01L 21/336; H01L 21/76

(52) U.S. Cl. 438/282; 438/424; 257/E21.54; 257/E21.428

(57) ABSTRACT

A method for fabricating recess channel MOS transistors of the present invention utilizes a lithography process to form trenches in the recess channel MOS transistors after finishing a STI process. Furthermore, the method of the present invention can make the critical dimension variation to be controlled in a range required in the precision semiconductor process. Therefore, the short problem between the transistors can be avoided.

### BACKGROUND OF THE INVENTION

1. Field of the Invention

The present invention relates to a method for fabricating semiconductor devices. More specifically, the present invention relates to a method for fabricating a recess channel Metal-Oxide-Semiconductor (MOS) transistor device of a trench type Dynamic Random Access Memory (DRAM).

2. Description of the Prior Art

Integrated circuit devices are continually being made smaller in order to increase speed, make the device more portable, and reduce the cost of manufacturing the device. However, certain designs have a minimum feature size, which cannot be reduced without compromising the integrity of electrical isolation between devices and consistent operation of the device. For example, dynamic random access memory devices (DRAMs), which utilize vertical metal oxide semiconductor field effect transistors (MOSFETs) with deep trench (DT) storage capacitors, have a minimum feature size of approximately 70 nm to 0.15 μm. Below that size, the internal electric fields exceed the upper limit for storage node leakage, which decreases retention time below an acceptable level. Therefore, there is a need for different methods and/or different structures to further reduce the size of integrated circuit devices.

With the continued reduction in device size, sub-micron scale MOS transistors must overcome many technical challenges. As MOS transistors become narrower (that is, their channel length decreases), problems such as junction leakage, source/drain breakdown voltage, and data retention time become more pronounced.

One solution to decreasing the physical dimension of ULSI circuits is to form recessed-gate or “trench-typed” transistors, which have a gate electrode buried in a groove formed in a semiconductor substrate. This type of transistor reduces short channel effect by having the gate extend into the semiconductor substrate to effectively lengthen the effective channel length.

The recessed-gate MOS transistor has a gate insulation layer formed on the sidewalls and bottom surface of a recess formed in a substrate, a conductive material filling the recess, contrary to a planar gate type transistor having a gate electrode formed on a planar surface of a substrate.

However, the aforesaid recessed-gate structure has some shortcomings. For example, gate trenches of the conventional hole-typed recessd-channel MOS transistor device are formed in the semiconductor substrate by utilizing a lithography process and dry etching process. When utilizing the lithography process to form the hole-typed gate trenches, the hole contour is not easy to control, and the critical dimension variation cannot be controlled in a range (3 sigma, 1 5nm) required in semiconductor processes under 60nm. Therefore, the short problem between the transistors will occur.

### SUMMARY OF THE INVENTION

One objective of this invention is to provide a method for fabricating a recess channel MOS transistor in order to solve the above mentioned problems.

According to the claimed invention, a method for fabricating a recess channel MOS transistor device includes: providing a semiconductor substrate having a main surface and a pad layer formed thereon; forming a plurality of trench capacitors in the semiconductor substrate, wherein each of the trench capacitors has a trench top oxide (TTO) layer, and top surfaces of the TTO layers are higher than the main surface of the semiconductor substrate; etching the TTO layers to make the top surfaces of the TTO layers as high as the main surface of the semiconductor substrate and form a plurality of recess openings in the pad layer; forming a first polysilicon layer on the TTO layers to fulfill the recess openings, wherein a top surface of the first polysilicon layer is as high as the pad layer; forming a plurality of shallow trench isolation (STI) structures parallel with each other in the semiconductor substrate and the pad layer; forming a oxide layer, a second polysilicon layer, and a first pattern photoresist layer in sequence on the STI structures, the first polysilicon layer, and the pad layer, wherein the first pattern photoresist layer interlaces with the STI structures; forming a pattern hard mask layer and respectively forming at least a first recess area and at least a second recess area in each of the STI structures and the pad layer, and forming a recess channel in the semiconductor substrate under each of the second recess areas; forming a gate dielectric layer in each of the recess channels to fulfill a first polysilicon layer therein; etching back the first polysilicon layer and the gate dielectric layer and forming an internal spacer on sidewalls of each of the recess channels; forming a first gate material layer in each of the recess channels; forming a gate dielectric layer on a bottom of each of the recess channels; forming an internal spacer on a sidewall of each of the recess channels; forming a second polysilicon layer on the semiconductor substrate, the first recess area, and the second recess area to fulfill the recess channel; and performing an etching back process and a planarizing process to make the top surfaces of the STI structures and the pad layer as high as the main surface of the semiconductor substrate.

According to the claimed invention, a method for fabricating a recess channel MOS transistor device includes: providing a semiconductor substrate having a main surface; forming a pad layer formed on the semiconductor substrate; forming a plurality of shallow trench isolation (STI) structures parallel with each other in the semiconductor substrate and the pad layer; respectively forming at least a first recess area and at least a second recess area in the STI structures and the pad layer, and forming a recess channel in the semiconductor substrate under each of the second recess areas; forming a gate dielectric layer on a bottom of each of the recess channels; forming an internal spacer on a sidewall of each of the recess channels; forming a polysilicon layer on the semiconductor substrate, the first recess area, and the second recess area to fulfill the recess channel; and performing an etching back process and a planarizing process to make the top surfaces of the STI structures and the pad layer as high as the main surface of the semiconductor substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 are 3D schematic diagrams illustrating an exemplary method of fabricating a recess channel MOS transistor device in accordance with a first embodiment of this invention.

FIGS. 8-9 are cross-sectional schematic diagrams illustrating an exemplary method of fabricating a recess channel MOS transistor device in accordance with a second embodiment of this invention.

FIGS. 11-13 are top-view schematic diagrams showing the method of fabricating the recess channel MOS transistor device in accordance with the second embodiment of this invention.

FIG. 10, 12, and FIG. 14-17 are 3D schematic diagrams illustrating the method of fabricating the recess channel MOS transistor device in accordance with the second embodiment of this invention.

### DETAILED DESCRIPTION

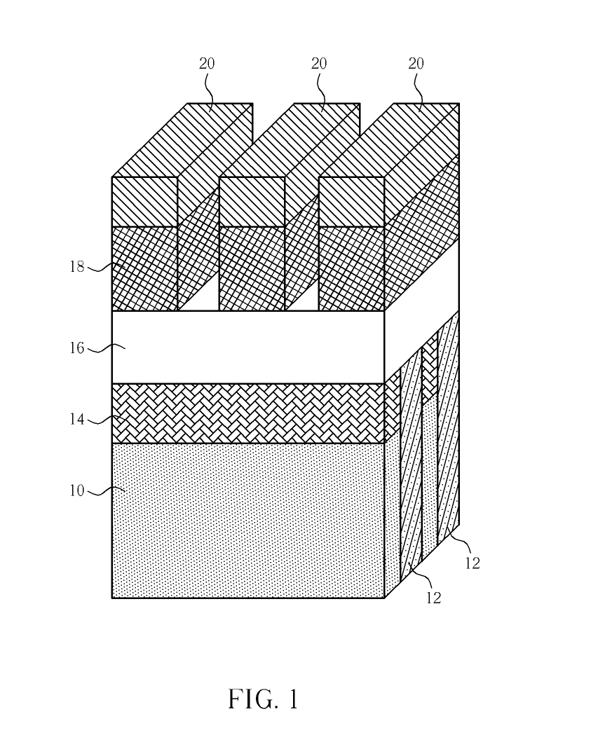

Please refer to FIGS. 1-7. FIGS. 1-7 are 3D schematic diagrams illustrating an exemplary method of fabricating a recess channel MOS transistor device in accordance with a first embodiment of this invention.

As shown in FIG. 1, an active area defining process and shallow trench isolation (STI) process for the semiconductor substrate 10 are performed. A plurality of STI structures 12 are formed in the semiconductor substrate and the STI structures 12 are parallel with each other. Please note that in the first embodiment of this invention, the deep trench capacitors are fabricated on the semiconductor substrate 10 before the active area defining process and STI process in FIG. 1 are performed. A pad layer 14 is formed between the STI structures 12 on the top surface of the semiconductor substrate 10. The pad layer 14 is interlaced with the STI structure 12. The position of the pad layer 14 is the active area of the semiconductor substrate 10, wherein the pad layer 14 can be oxide layers or silicon nitride layers. Next, a BSG layer 16, a polysilicon layer 18, and a photoresist layer 20 are formed on the pad layer 14 and each STI structure 12 in sequence, wherein the photoresist layer 20 is defined with a pattern of a plurality of parallel lines interlaced with each STI structure 12. An etching process is performed to transfer the line pattern of the photoresist layer 20 to the polysilicon layer 18 to make it become a hard mask layer, and then the photoresist layer 20 is removed. In this embodiment, the direction of the parallel lines is vertical to that of each STI structure 12.

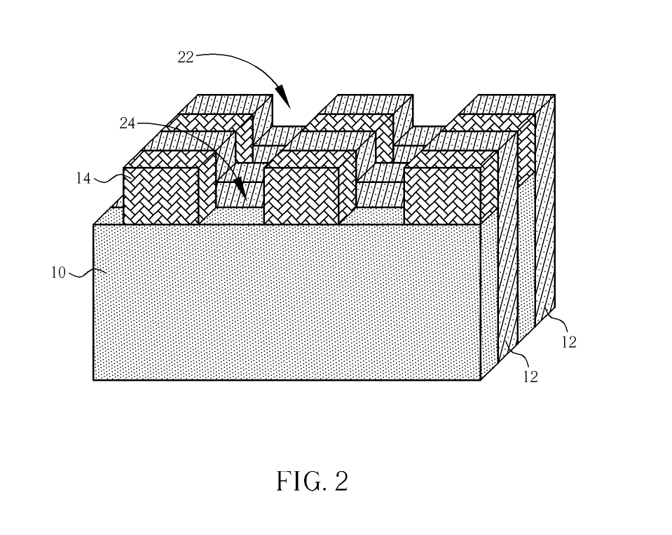

Next, as shown in FIG. 2, the polysilicon layer 18 is utilized as an etching hard mask to etch the BSG layer 16, the pad layers 14, and the STI structures 12 to form a plurality of first recess areas 22 in the STI structure 12 and second recess areas 24 in the active area. The bottom of each first recess area 22 is higher than the top surface of the semiconductor substrate 10, and the second recess areas 24 expose a part of the top surface of the semiconductor substrate 10. This is a result of utilizing a property of etching selectivity between the STI structures 12 (such as oxide layers) and the pad layer 14 (such as silicon nitride layers) in this invention.

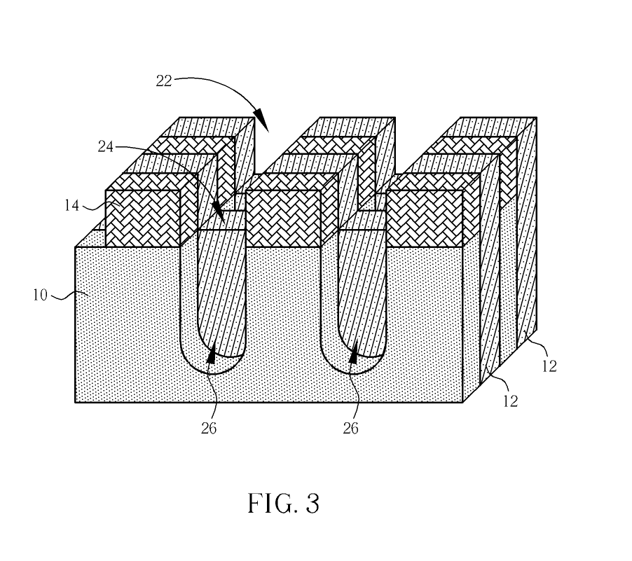

Next, as shown in FIG. 3, the STI structure 12 and the pad layer 14 are utilized as an hard mask to etch each second recess area 24 to form a recess channel 26 in the semiconductor substrate 10 in each second recess area 24. Generally, the bottom of each first recess area 22 will be as high as or higher than the top surface of the semiconductor substrate 10 after each recess channel 26 is formed.

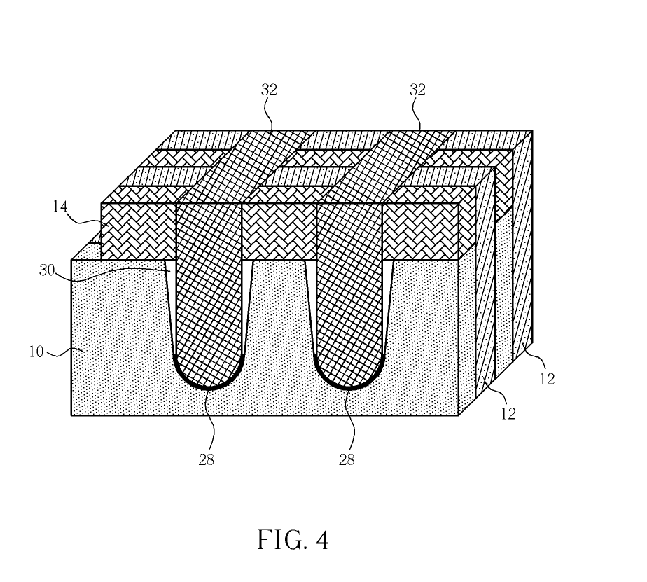

Next, as shown in FIG. 4, a gate dielectric layer 28 is formed on the bottom of each recess channel 26, and an internal spacer 30 is formed on a sidewall of each recess channel 26. Then, a first polysilicon layer 32 is formed on the semiconductor substrate 10, each first recess area 22, and each second recess area 24 to fill each recess channel 26.

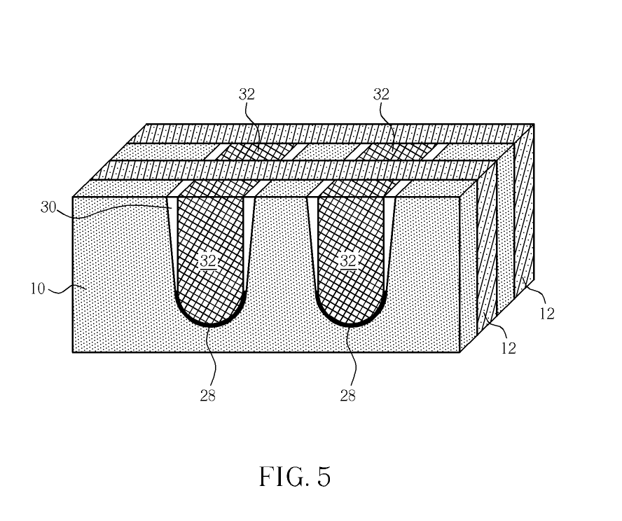

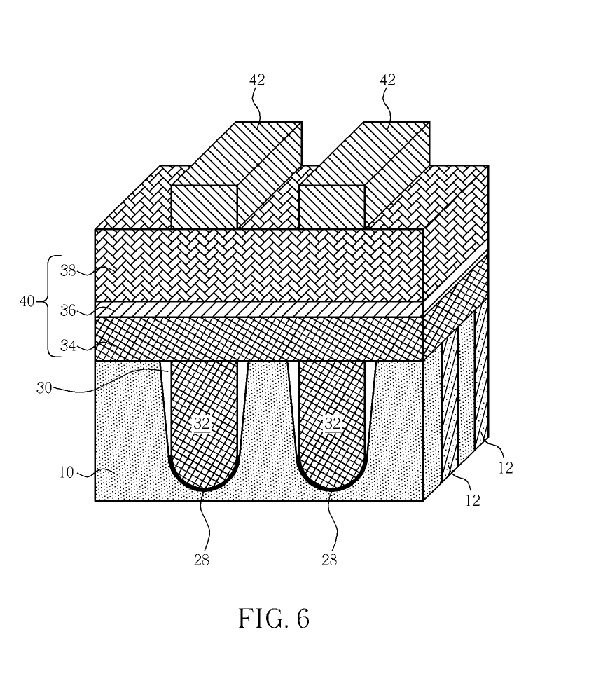

Next, as shown in FIG. 5, a planarizing process such as a CMP process is performed to remove the pad layer 14, and the STI structure 12 and the first polysilicon layer 32 have the same height as the top surface of the substrate.

Next, as shown in FIG. 6, a polysilicon layer34, a wolfram (W) metal layer 36 and a silicon nitride layer 38 are deposited on the semiconductor substrate 10 in sequence to form a gate material layer 40, and a patterned photoresist layer 42 is formed on the gate material layer 40 above the recess channels 26. In this embodiment, the direction of the patterned photoresist layer 42 is vertical to each STI structure 12.

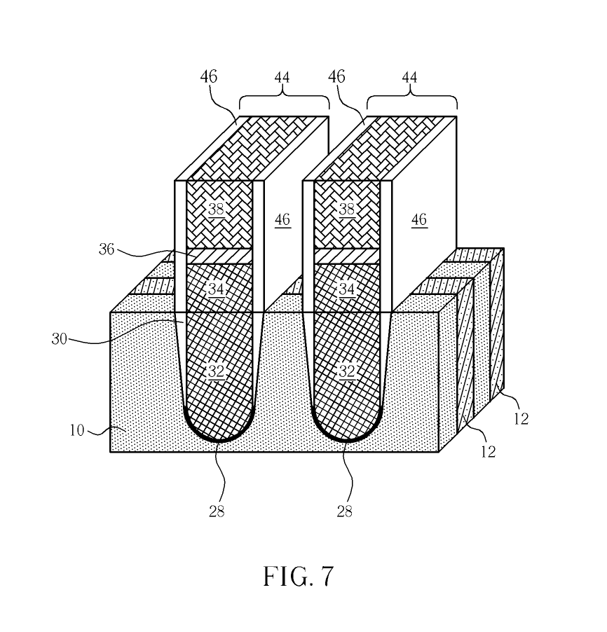

Finally, as shown in FIG. 7, the patterned photoresist layer 42 is utilized as an etching mask to etch the gate material layer 40 to form a plurality of gate conductor 44, and a spacer 46 is formed on a sidewall of each gate conductor 44. Next, an ion implantation process can be performed to form different doped areas (the source, drain, etc) in the semiconductor substrate 10, to form NMOS transistors or PMOS transistors.

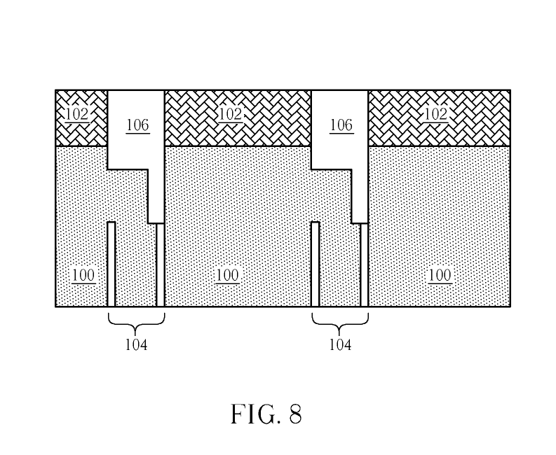

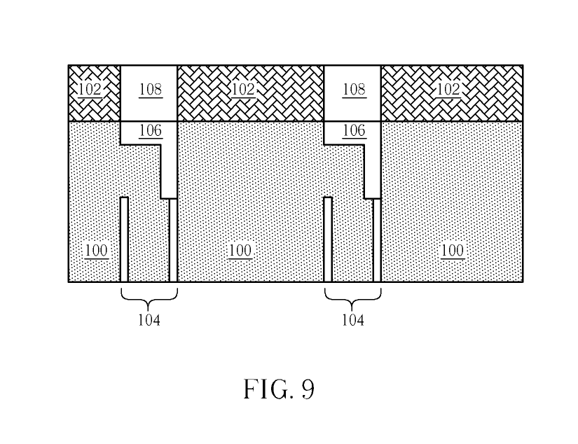

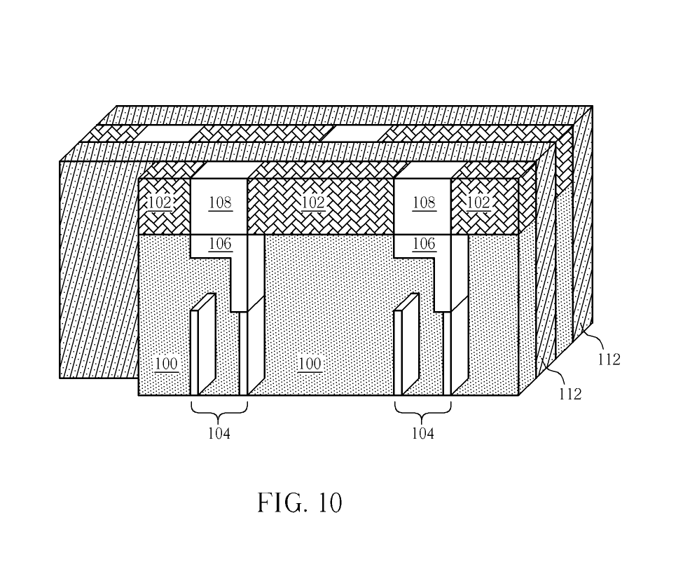

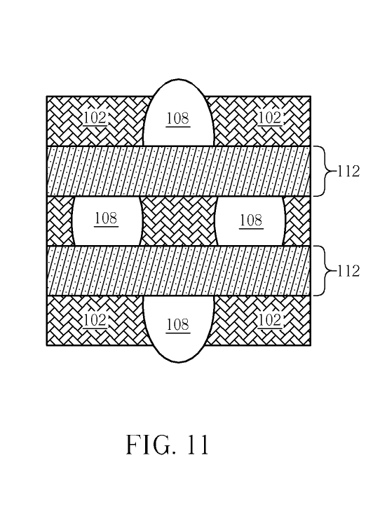

Please refer to FIGS. 8-17. FIGS. 8-9 are cross-sectional schematic diagrams illustrating an exemplary method of fabricating a recess channel MOS transistor device in accordance with a second embodiment of this invention. FIG. 11-13 are top-view schematic diagrams showing the method of fabricating the recess channel MOS transistor device in accordance with the second embodiment of this invention. FIG. 10, 12, and FIG. 14-17 are 3D schematic diagrams illustrating the method of fabricating the recess channel MOS transistor device in accordance with the second embodiment of this invention.

Firstly, as shown in FIG. 8, a Single-Sided Buried Strap (SSBS) process is performed in a semiconductor substrate 100 and a pad layer 102 to form a plurality of trench capacitor connecting area structures 104. The method of fabricating the trench capacitor connecting area structures 104 is known in the art, and thus further explanation of the detailed fabricating process are omitted herein for the sake of brevity. Additionally, there is a trench top oxide (TTO) layer 106 on each of the trench capacitor connecting area structures 104.

Next, an etching process is performed to etch the TTO layer 106 to make the top surfaces of the TTO layers 106 a little higher than or level with the main surface of the semiconductor substrate 100, and form a plurality of recess openings in the pad layer 102. Then, a first polysilicon layer 108 is formed on the TTO layers 106 (i.e. inside the recess openings) to fill the recess openings. Next, a planarizing process such as a CMP process is performed to make the top surface of first polysilicon layer 108 level with the top surface of the pad layer 102 as shown in FIG. 9.

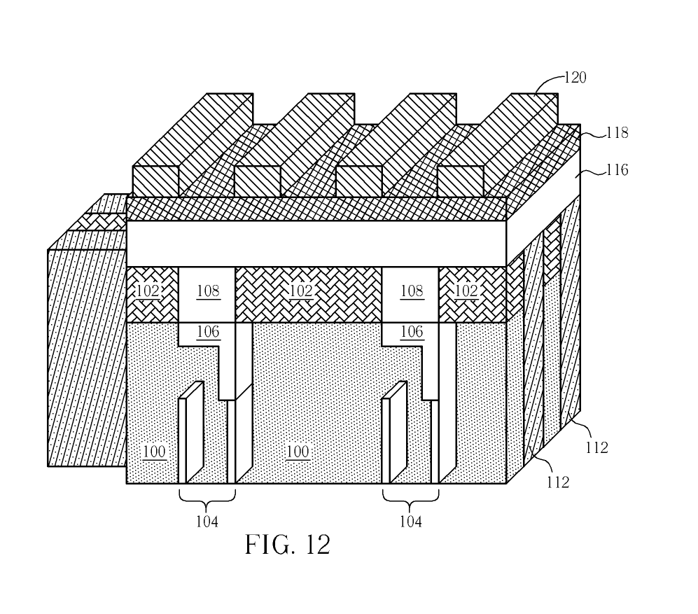

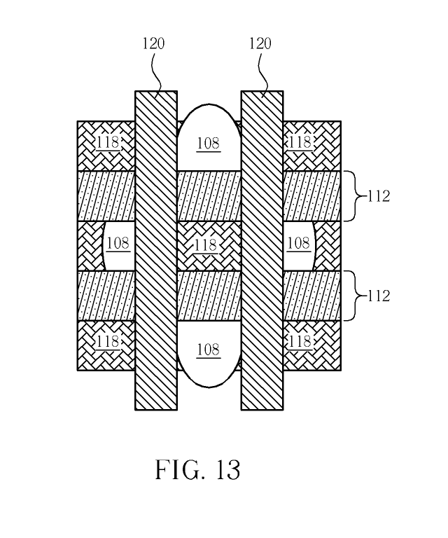

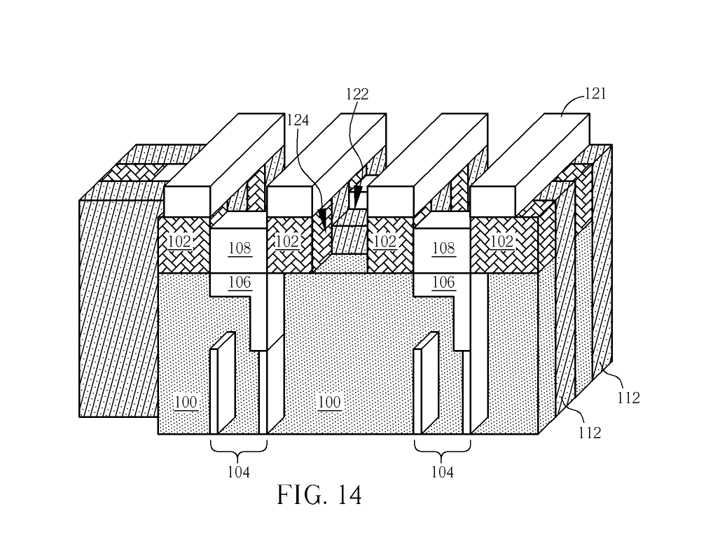

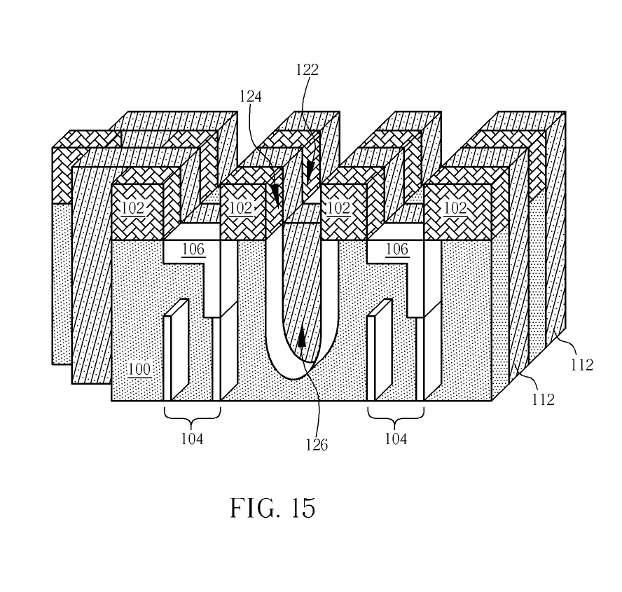

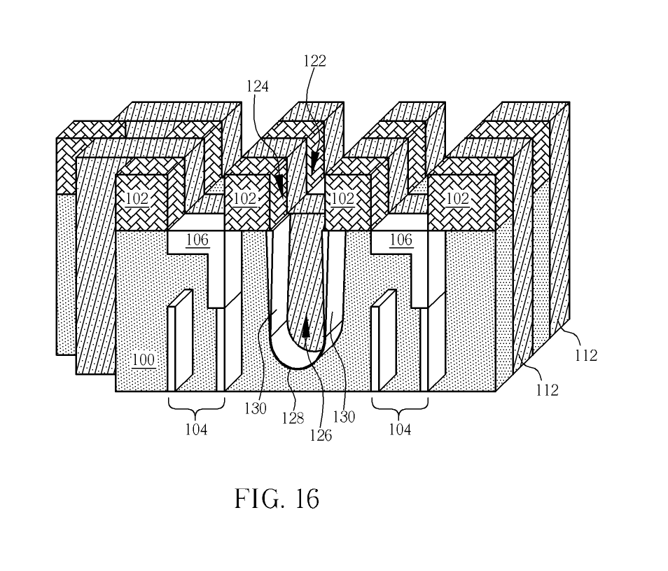

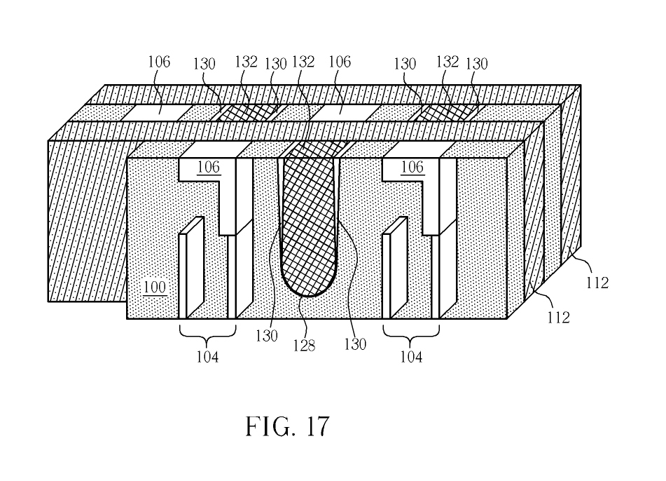

Next, as shown in FIG. 10, an active area defining process and shallow trench isolation (STI) process for the semiconductor substrate 100 are performed. A plurality of STI structures 112 are formed in the semiconductor substrate and in parallel with each other. The position of each pad layer 102 is the active area of the semiconductor substrate 100, as shown in FIG. 11. Next, as shown in FIG. 12, a BSG layer 116, a second polysilicon layer 118, and a photoresist layer 120 are formed on each pad layer 102 and each STI structure 112 in sequence, wherein the photoresist layer 120 is defined with a pattern of a plurality of parallel lines interlaced with each STI structure 12, as shown in FIG. 13. In this embodiment, the direction of the parallel lines is vertical to each STI structure 12.

Next, an etching process is performed to utilize the photoresist layer 120 to pattern the second polysilicon layer 118. After the photoresist layer 120 is removed, the patterned second polysilicon layer 118 is utilized as an etching mask to etch the BSG layer 116, the STI structures 112, and the pad layers 102 to form a patterned hard mask layer 121, and to form a plurality of first recess areas 122 and second recess areas 124. The bottom of each first recess area 122 is higher than the main surface of the semiconductor substrate 100, and the second recess areas 124 expose a part of the main surface of the semiconductor substrate 100, as shown in FIG. 14.

Next, the patterned hard mask layer 121 is utilized to etch each first recess area 122 and each second recess area 124 simultaneously and form a recess channel 126 in the semiconductor substrate 100 under each second recess area 124. Then, VHF is utilized to remove the patterned hard mask layer 121 as shown in FIG. 15. Generally, the bottom of each first recess area 122 will be level with or higher than the main surface of the semiconductor substrate 100 after each recess channel 126 is formed.

Next, as shown in FIG. 16, a gate dielectric layer 128 is formed on the bottom of each recess channel 126, and an internal spacer 130 is formed on a sidewall of each recess channel 126. Then, a second polysilicon layer 132 is formed on the semiconductor substrate 100, each first recess area 122, and each second recess areas 124 to fill each recess channel 126. Next, the second polysilicon layer 132 is etched back so that the top surface of the second polysilicon layer 132 is level with the main surface of the semiconductor substrate 100. Then, a planarizing process such as a CMP process is performed to make the top surfaces of each STI structure 112 as high as the main surface of the semiconductor substrate 100, and the pad layers 102 are removed, as shown in FIG. 17. Please note that since the following process of the second embodiment of this invention is similar to the process of FIG. 6, 7 in the first embodiment of this invention, thus further explanation is omitted herein for the sake of brevity.

In brief, the method for fabricating a recess channel MOS transistor device of the present invention utilizes a lithography process to form gate trenches in the recess channel MOS transistor device before finishing a STI process, and thus the critical dimension variation can be decreased. This is because the line pattern variation is obviously lower than the hole pattern variation for the lithography process.

Those skilled in the art will readily observe that numerous modifications and alterations of the device and method may be made while retaining the teachings of the invention.

What is claimed is:

1. A method for fabricating trenches in a substrate comprising:
forming a plurality of isolation regions in the substrate, wherein the plurality of isolation regions are parallel to each other;
forming a patterned pad layer on the substrate and the plurality of isolation regions to partially expose the substrate and the plurality of isolation regions; and
partially removing the exposed substrate by using the patterned pad layer and the exposed plurality of isolation regions as hard masks so that the trenches are formed.

2. The trenches fabricating method as claimed in claim 1, wherein the patterned pad layer is formed with a plurality of recessed areas extended in a first direction.

3. The trenches fabricating method as claimed in claim 2, wherein the isolation regions is extended in a second direction, and the first direction is perpendicular to the second direction.

4. A method for fabricating a MOS transistor device with a recess channel, comprising:
providing a semiconductor substrate having at least two mutually parallel isolation regions therein;
forming a patterned pad layer on the semiconductor substrate;
partially removing the semiconductor substrate between the two mutually parallel isolation regions to form a channel in the semiconductor substrate;
forming a dielectric layer on a surface of the channel; and
forming a gate structure on the dielectric layer.

5. The MOS transistor device fabricating method as claimed in claim 4, wherein the portion of the semiconductor substrate removing step is performed by using the patterned pad layer and the two parallel isolation regions as hard masks to etch the semiconductor substrate.

6. The MOS transistor device fabricating method as claimed in claim 4, wherein the patterned pad layer is formed with a plurality of recessed areas extended in a first direction.

7. The MOS transistor device fabricating method as claimed in claim 6, wherein the isolation regions is extended in a second direction, and the first direction is perpendicular to the second direction.
